(19) United States
(12) Patent Application Publication
(10) Pub. No.: US 2020/0292596 A1
(43) Pub. Date: Sep. 17, 2020

(54) MONITORING SYSTEM

(71) Applicant: OMRON Corporation, Kyoto (JP)

(72) Inventors: Kunio AONO, Osaka (JP); Hideki OZEKI, Kashiba-shi (JP); Atsuo MINATO, Otsu-shi (JP); Kazuyoshi IMAMURA, Moriyama-shi (JP)

(73) Assignee: OMRON Corporation, Kyoto (JP)

(21) Appl. No.: 16/792,193

(22) Filed: Feb. 15, 2020

(30) Foreign Application Priority Data
Mar. 11, 2019 (JP) 2019-043668

(51) Int. Cl. G01R 19/25; G01R 21/00; H02J 13/00

(52) U.S. Cl. CPC G01R 19/2513; H02J 13/00001; G01R 21/005

(57) ABSTRACT

The monitoring system includes: a management server, and a transmission device which obtains, from the power storage system, first charged power index values indicating charged power of the power storage system and input/output power index values indicating input/output power from the power receiving point to which the power storage system is connected to a system, and transmits the index values to the management server via a network. The management server includes: a calculation part which calculates, based on the first charged power index values and the input/output power index values, second charged power index values indicating power charged by generated power of the power generation system connected to the power receiving point of charged power of the power storage system; and a diagnosis part which diagnoses presence or absence of abnormality of the power generation system based on the second charged power index values calculated by the calculation part.

### CROSS-REFERENCE TO RELATED APPLICATION

This application claims the priority benefits of Japan Patent Application No. 2019-043668, filed on Mar. 11, 2019. The entirety of the above-mentioned patent application is hereby incorporated by reference herein and made a part of this specification.

### BACKGROUND OF THE DISCLOSURE

### Technical Field

The disclosure relates to a monitoring system.

### Related Art

Conventionally, in order to be able to confirm (grasp) an action state of an apparatus with a smartphone or the like, information relating to the action state of the apparatus is collected by a management server on the Internet (for example, see patent literatures 1 (Japanese Patent Laid-Open No. 2000-076033) and patent literatures 2 (Japanese Patent Laid-Open No. 2007-221565)).

Similarly, for a power storage system, information relating to an action state is collected by a management server on the Internet.

When a power storage system is used alone, the action state of the power storage system can be grasped only by information from the power storage system; however, when the power storage system is used in combination with a power generation system, it is desirable that the action state of the power generation system (mainly presence or absence of abnormality) can also be grasped. When information relating to the action state can be obtained from the power generation system, the presence or absence of abnormality of the power generation system can be diagnosed based on the information. Therefore, the action state of the power storage system can also be accurately grasped, but when the power generation system is made by another company or when the power generation system does not have a function of outputting the information relating to the action state to an external device, the information relating to the action state cannot be obtained from the power generation system.

### SUMMARY

The disclosure is a monitoring system, including:
a calculation part for calculating, based on first charged power index values indicating charged power of an power storage system and input/output power index values indicating input/output power from a power receiving point to which the power storage system is connected to a system, second charged power index values indicating power charged by generated power of a power generation system connected to the power receiving point of the charged power of the power storage system; and
a diagnosis part for diagnosing presence or absence of abnormality of the power generation system based on the second charged power index values calculated by the calculation part.

### BRIEF DESCRIPTION OF THE DRAWINGS

FIG. 1 is a diagram illustrating a schematic configuration and a usage state of a monitoring system in Example 1 of the disclosure.

FIG. 2 is a schematic configuration diagram of a controller of a storage battery power conditioner in Example 1 of the disclosure.

FIG. 3 is a schematic configuration diagram of a monitoring device in Example 1 of the disclosure.

FIG. 4 is a flowchart showing a procedure of a charged power information transmission process in Example 1 of the disclosure.

FIG. 5 is a flowchart showing a procedure of a charged power information analysis process in Example 1 of the disclosure.

FIG. 6 is a diagram illustrating a calculation formula for charged power (self-consumption) of the disclosure.

FIG. 7 is a diagram illustrating another calculation formula of charged power (self-consumption) of the disclosure.

FIG. 8 is a flowchart showing a procedure of a calculation process of the charged power (self-consumption) in Example 1 of the disclosure.

FIG. 9 is a flowchart showing a procedure of a calculation process of the charged power (self-consumption) in Example 2 of the disclosure.

FIG. 10 is a flowchart showing a procedure of a charged power transmission process in Example 2 of the disclosure.

FIG. 11 is a flowchart showing a procedure of a charged power information analysis process in Example 2 of the disclosure.

FIG. 12 is a flowchart showing a procedure of a calculation/transmission process of the charged power (self-consumption) in Example 3 of the disclosure.

### DESCRIPTION OF THE EMBODIMENTS

The disclosure provides a monitoring system which can diagnose presence or absence of abnormality of a power generation system connected to a power receiving point the same as a power storage system without obtaining any information from the power generation system.

According to the disclosure, a power generation state of the power generation system connected to a power receiving point the same as the power storage system can be grasped by monitoring the second charged power index values indicating the power charged by the generated power of the power generation system connected to the power receiving point of the charged power of the power storage system, and thus the presence or absence of abnormality of the power generation system can be diagnosed without obtaining any information from the power generation system. In addition, according to the disclosure, the power generation state of the power generation system connected to the power receiving point the same as the power storage system is grasped by monitoring the second charged power index values indicating the power charged by the generated power of the power generation system connected to the power receiving point of the charged power of the power storage system, and thus even when the power storage system and the power generation system are operated in a mode in which the power is not sold to the system via the power receiving point, the presence or absence of abnormality of the power generation system can be diagnosed without obtaining any information from the power generation system.

It is desirable that the first charged power index values and the input/output power index values are continuously acquired for a plurality of times in a manner that the acquisition is performed every day at a predetermined time zone. In this way, the presence or absence of abnormality of the power generation system can be diagnosed in distinction from a case where a power generation amount of the power generation system is temporarily reduced.

Here, the network includes, for example, the Internet, but is not limited thereto, and the disclosure can be applied to various networks such as an intranet and the like. In addition, the network may be connected by either a wired or wireless communication line.

In addition, in one embodiment of the disclosure, the diagnosis part may diagnose that there is an abnormality in the power generation system when a first predetermined number of the second charged power index values are all “0”.

Accordingly, since the second charged power index values are continuously “0” and the generated power from the power generation system is not continuously generated, it can be diagnosed that there is an abnormality in the power generation system.

In addition, in one embodiment of the disclosure, the diagnosis part may diagnose that there is an abnormality in the power generation system when a second predetermined number of the second charged power index values are equal to or less than a predetermined amount.

Accordingly, since the second charged power index values are continuously equal to or less than the predetermined amount and the generated power from the power generation system is continuously decreasing, it can be diagnosed that there is an abnormality in the power generation system.

In addition, in one embodiment of the disclosure, the power generation system may include a DC power generation device and a power conditioner which converts DC power from the DC power generation device to AC power; and the diagnosis part may diagnose that there is an abnormality in the power conditioner of the power generation system when the first predetermined number of the second charged power index values are all “0”, and diagnose that there is an abnormality in the DC power generation device of the power generation system when the second predetermined number of the second charged power index values are equal to or less than the predetermined amount.

In this way, the monitoring system can be provided in which when the power generation system includes the DC power generation device and the power conditioner which converts DC power from the DC power generation device into AC power, the presence or absence of the power generation system can be diagnosed without obtaining any information from the power generation system.

In addition, in one embodiment of the disclosure, when the diagnosis part diagnoses that there is an abnormality in the power generation system, a notification process for notifying a user of the power storage system of this diagnosis may be performed.

In this way, the user can recognize the presence or absence of abnormality of the power generation system diagnosed by the management server.

According to the disclosure, the monitoring system can be provided which can diagnose the presence or absence of abnormality of the power generation system connected to the power receiving point the same as the power storage system without obtaining any information from the power generation system.

### APPLICATION EXAMPLES

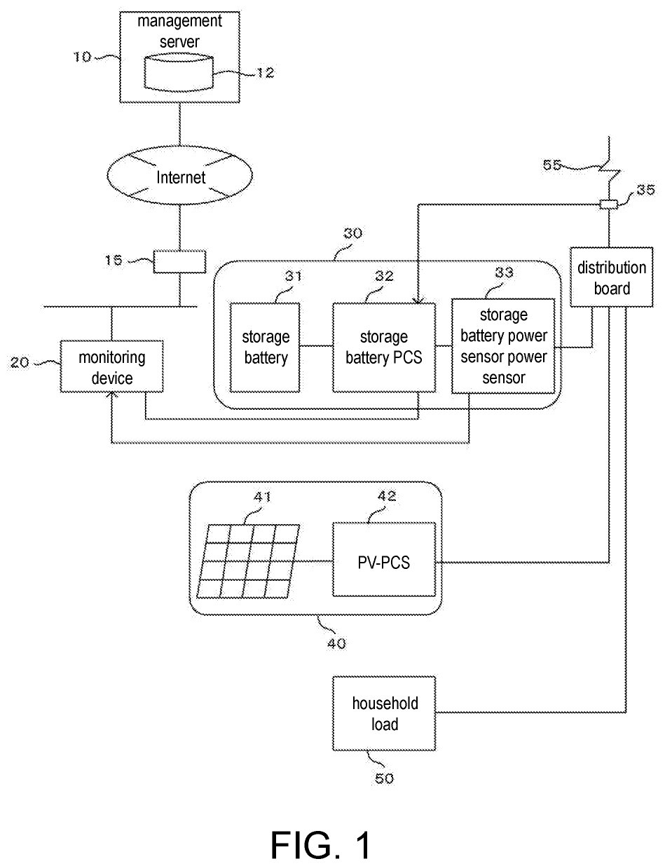

Application examples of the disclosure are described below with reference to the drawings. FIG. 1 is a diagram illustrating a schematic configuration and a usage state of a monitoring system according to Example 1 of the disclosure.
A power generation system 40 may be made by another company, or the power generation system 40 may not have a function of outputting information relating to an action state to an external device. In this case, in order to diagnose presence or absence of abnormality in the power generation system 40 connected to a power receiving point 55 the same as a power storage system 30 without obtaining any information from the power generation system 40, it is conceivable to detect a failure of the power generation system by monitoring power reversely flowed from the power receiving point 55 to a system.

In general, when the power storage system 30 and the power generation system 40 are used in combination, there are a power sale priority mode which is a so-called economic mode, and a mode for self-consumption which is a so-called green mode.
In the economic mode, at night, a storage battery 31 is charged with inexpensive late-night power supplied from the system and is used for a household load 50 as necessary. Besides, during the daytime, when power consumption of the household load 50 cannot be covered by generated power of a PV 41, power of the storage battery 31 is discharged and used for the household load 50. In addition, when the generated power of the PV 41 exceeds the power consumption of the household load 50, the power is sold by reversely flowing the power to the system via the power receiving point 55.
When the power generation system is run in the economic mode, the failure of the power generation system can be detected as described above by monitoring the power reversely flowed to the system from the power receiving point 55.

However, in the green mode, the generated power of the PV 41 is entirely consumed at home without being sold to the system. That is, in this case, since basically the power is not reversely flowed to the system, it is not effective to detect the failure of the power generation system 40 by monitoring the power reversely flowed to the system as described above. However, even in the green mode, in order to make more use of the storage battery 31, the storage battery 31 may also be charged with the inexpensive late-night power.
The disclosure can detect, even when the power storage system 30 and the power generation system 40 are used in combination in this so-called green mode, the failure of the power generation system 40 by monitoring charged power of the storage battery 31, especially the charged power (self-consumption) that is a part of the charged power and is carried by the generated power of PV 41 without obtaining any information from the power generation system 40.

The monitoring system of the disclosure includes: a calculation part for calculating, based on first charged power index values indicating charged power of an power storage system and input/output power index values indicating input/output power amount from a power receiving point to which the power storage system is connected to a system, second charged power index values indicating power charged by generated power of a power generation system connected to the power receiving point of the charged power of the power storage system; and a diagnosis part for diagnosing presence or absence of abnormality of the power generation system based on the second charged power index values calculated by the calculation part.
When the disclosure is applied to the monitoring system including the management server 10, the monitoring device 20, the power storage system 30, and the power generation system 40, the first charged power index values and the input/output power index values obtained from the power storage system 30 are transmitted to the management server 10 using the monitoring device 20 as a transmission device, and the management server 10 can be configured to include the calculation part and the diagnosis part.
In addition, when the disclosure is applied to a monitoring system including the management server 10, the monitoring device 20, the power storage system 30, and the power generation system 40, a storage battery power conditioner 32 of the power storage system 30 (hereinafter referred to as the storage battery PCS) can be configured to include the calculation part. In this case, the calculated second charged power index values can be transmitted to the management server 10 using the monitoring device 20 as a transmission device, and the management server 10 can be configured to include the diagnosis part.
In addition, when the disclosure is applied to a monitoring system including the management server 10, the monitoring device 20, the power storage system 30, and the power generation system 40, the monitoring device 20 can be configured to include the calculation part. In this case, the calculated second charged power index values can be transmitted to the management server 10 using the monitoring device as a transmission device, and the management server 10 can be configured to include the diagnosis part.

### Example 1

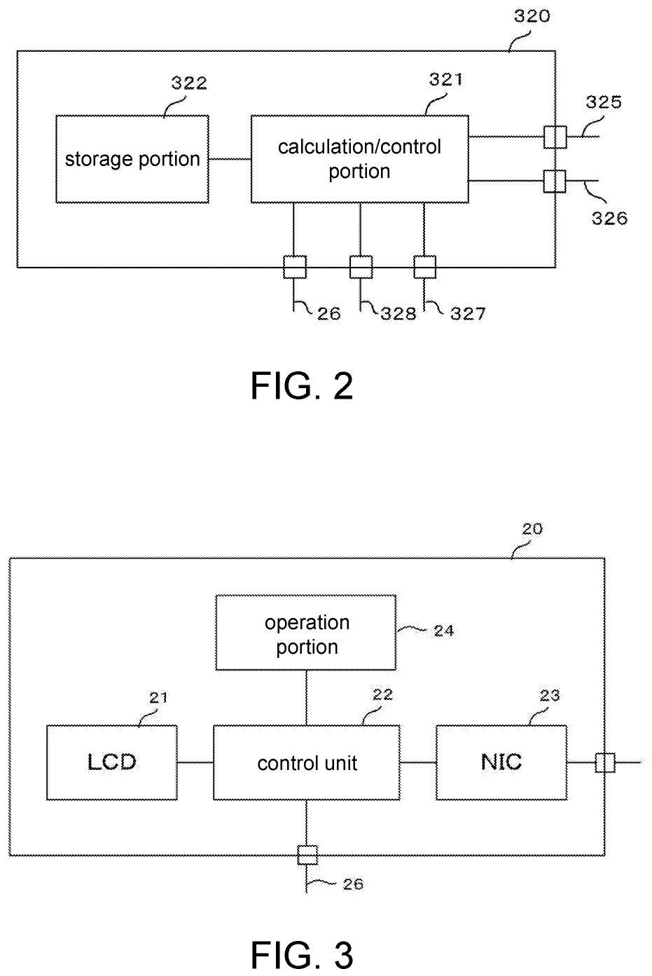

A monitoring system according to Example 1 of the disclosure is described more specifically below using the drawings.

<System Configuration>
An overview of the monitoring system according to the example of the disclosure is described using FIG. 1, FIG. 2 and FIG. 3. FIG. 1 is an illustrative diagram of a schematic configuration and a usage form of the monitoring system according to the example, FIG. 2 is a schematic configuration diagram of a controller of a storage battery PCS, and FIG. 3 is a schematic configuration diagram of a monitoring device which is a component of the monitoring system.

As shown in FIG. 1, the monitoring system according to the example includes a management server 10, a power storage system 30 combined with a power generation system 40, and a monitoring device 20. Moreover, “combined with the power generation system 40” means “connected to a power receiving point 55 to which the power generation system 40 is connected”. In addition, FIG. 1 shows one power storage system 30 and one monitoring device 20, but the monitoring system is usually built as a system which includes a plurality of the power storage systems 30 and the monitoring devices 20 prepared for each power storage system 30.

The power storage system 30 is a system which includes a storage battery PCS 32 and a storage battery power sensor 33 which perform charge/discharge control of the storage battery 31 on the storage battery 31. The storage battery power sensor 33 is not necessarily limited to being configured as a device independent of the storage battery PCS 32. The storage battery power sensor 33 may be configured by a function of the storage battery PCS 32 of measuring a charged power amount of the storage battery and may constitute a part of the storage battery PCS32. FIG. 2 shows a schematic configuration of a controller 320 of the storage battery PCS 32. The controller 320 includes a calculation/control portion 321 and a storage portion 322. The calculation/control unit 321 is configured by a processor such as a CPU or the like, and achieves various functions described later by executing a program. The storage portion 322 includes a main storage device in which the program or data executed by the calculation/control portion 321 are expanded, and an auxiliary storage device which stores the program or the data (including an apparatus ID described later). A connection line 325 is connected to a current sensor 35, and a connection line 326 is connected to the storage battery power sensor 33. In addition, a connection line 327 is connected to the storage battery 31, and a connection line 328 is connected to each component of the storage battery PCS 32. Besides, a connection line 26 is a communication cable connected to the monitoring device 20. An A/D converter or a D/A converter is arranged depending on a format of signals input/output through each connection line, but is omitted in the drawings. The storage battery PCS 32 configuring the power storage system 30 has a function of controlling, based on output of the current sensor 35 for detecting a current flowing out to the system (reverse flow) or a current flowing from the system, the storage battery 31 in a manner that the power stored in the storage battery 31 is not reversely flowed (not sold). The storage battery PCS 32 also has the following functions.

A state value detection function of detecting various state values (a remaining power storage amount or a reversely flowed power amount of the storage battery 31) representing the action state of the power storage system 30
An error detection function of detecting errors occurring in the power storage system 30 (the storage battery PCS 32 and the storage battery 31)
An information output function of returning, to the monitoring device 20, information requested by the monitoring device 20 connected by the communication cable 26 Moreover, the information which can be provided to the monitoring device 20 by the information output function of the storage battery PCS 32 includes the state values detected by the state value detection function, status information indicating a present state of the power storage system 30 (normal or during error occurrence), and the apparatus ID assigned to the storage battery PCS 32, and the like.

The power generation system 40 combined with the power storage system 30 may be a system connected to a commercial power system via the power receiving point. However, in the following description, the power generation system 40 is a solar power generation system in which a photovoltaic array 41 (hereinafter referred to as the PV 41) and a PV power conditioner (hereinafter referred to as the PV-PCS) 42 are combined. Here, the PV 41 corresponds to a DC power generation device and the PV-PCS 42 corresponds to a power conditioner which converts DC power into AC power.

The management server 10 is a Web server including a large-capacity nonvolatile storage device (such as a hard disk or the like), a control unit centered on a processor, and an NIC (Network Interface Card) as main components. The management server 10 includes a power storage system management database 12 for storing various types of information transmitted from the monitoring device 20 for each power storage system 30 to each power storage system 30. The power storage system management database 12 (hereinafter also referred to as the management DB 12) also stores information (e-mail address, login information) for users (owners, or the like) of each power storage system 30. Based on the information in the management DB 12, the management server 10 performs a process of providing each user with a web page on which the action status of the power storage system 30 can be confirmed, or a process of notifying each user of an error occurrence by e-mail.

The monitoring device 20 is a device for notifying the user and the management server 10 of the action state of the power storage system 30. As shown in FIG. 3, the monitoring device 20 includes an LCD (Liquid Crystal Display) 21, a control unit 22, a NIC 23, and an operation portion 24.

The NIC 23 is an interface circuit for communicating with the management server 10. The monitoring device 20 is usually connected to the Internet via a router 15.

The operation portion 24 is a unit including a plurality of push button switches. The control unit 22 is a unit in which a processor (CPU, microcontroller, or the like) and its peripheral circuits are combined. The control unit 22 acts as follows based on set program and information (such as an address of the management server 10 and the like).

When the power is turned on, the control unit 22 communicates with the connected storage battery PCS 32 to thereby grasp the apparatus ID of the storage battery PCS 32 (hereinafter referred to as self-apparatus ID). Then, the control unit 22 shifts to a normal state.

The control unit 22 which has shifted to the normal state accepts display instructions for various types of information (a remaining power storage amount, a charged/discharged power amount, error in occurrence, and the like) from the user through an operation on the operation portion 24. When receiving a display instruction for certain information, the control unit 22 acquires the information from the storage battery PCS 32 and displays the information on the LCD 21.

The configuration and the action of the monitoring system according to the example are described below more specifically.
As described above, the monitoring device 20 (control unit 22) can acquire the information relating to the action state of the power storage system 30 by communicating with the storage battery PCS 32. However, the monitoring device 20 is not configured to be able to communicate with the PV-PCS 42 (see FIG. 1). Therefore, the monitoring device 20 cannot obtain information relating to the action state from the PV-PCS 42, but in order to accurately grasp the action state of the power storage system 30, it is better to know the action state of the power generation system 40.

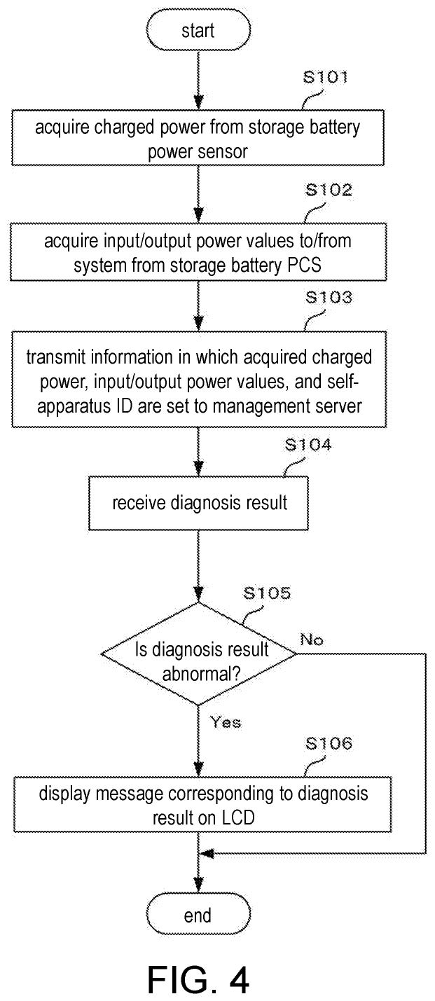

In order to be able to grasp the action state of the power generation system 40, the control unit 22 of the monitoring system according to the embodiment has a function of performing an information transmission process (hereinafter referred to as a charged power information transmission process) relating to charged power of the storage battery and input/output power values to/from the system every day at a predetermined time (for example, 12:00), the procedure of the process being shown in FIG. 4. In addition, the management server 10 has a function of performing a charged power information analysis process during reception of the values of the charged power of the storage battery and the input/output power to/from the system (details will be described later), the procedure of the process being shown in FIG. 4. Here, the function of performing the charged power information analysis process corresponds to the diagnosis part.

<Charged Power Information Transmission Process, Charged Power Information Analysis Process and Charged Power (Self-Consumption) Calculation Process>
That is, as shown in FIG. 4, the control unit 22 acquires, at a predetermined time every day, the charged power of the storage battery 31 from the storage battery power sensor 33 (step S101) and acquires the input/output power values to/from the system from the storage battery PCS 32 (step S102). Here, the charged power of the storage battery 31 is an index value of the amount of power charged into the storage battery within a predetermined time. The charged power of the storage battery 31 may be a charged power amount or a received current value and a charged voltage value as long as the amount of power charged to the storage battery within a predetermined time is known.

In addition, the process in step S101 may be a process of acquiring values which have already been measured from the storage battery power sensor or a process of causing the storage battery power sensor to perform a new measurement. Furthermore, the input/output power value to/from the system is an example of an input/output power index value indicating an index of the amount of power flowing from the system within a predetermined time or the amount of power reversely flowed to the system within a predetermined time. As long as the inflow or reversely flowed power amount within a predetermined time is known, the input/output power index values to/from the system may be the inflow or reversely flowed power amount, or values which may be obtained by calculating the input/output power values, such as inflow current values or a reversely flowed current values measured by the current sensor 35 and a system voltage measured by the storage battery PCS 32. In addition, the process in step S102 may be a process of acquiring the values which have been measured from the storage battery PCS or a process of causing the storage battery PCS 32 to perform a new measurement of the input/output values. Here, the charged power corresponds to first power index values, and the input/output power values to/from the system correspond to the input/output power index values.

The control unit 22 which has ended the processes in step S101 and step S102 transmits the charged power information in a predetermined format, in which the acquired charged power, the input/output power values, and the self-apparatus ID are set, to the management server 10 using the NIC 23 (step S103).

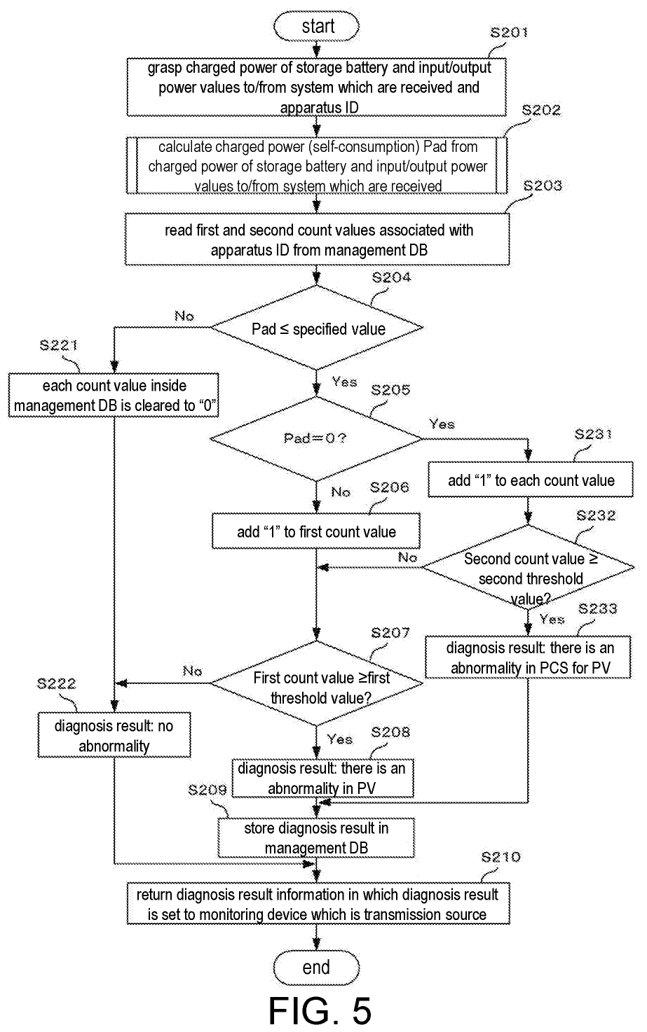

The management server 10 which receives the charged power information starts the charged power information analysis process (FIG. 5), and first grasps the charged power, the input/output power values, and the apparatus ID which are set in the received charged power information (step S201). Next, the management server 10 calculates charged power (self-consumption) based on the charged power and the input/output power values set in the received charged power information (step S202). Here, the charged power (self-consumption) corresponds to the second charged power, and the function of calculating the charged power (self-consumption) corresponds to the calculation part.

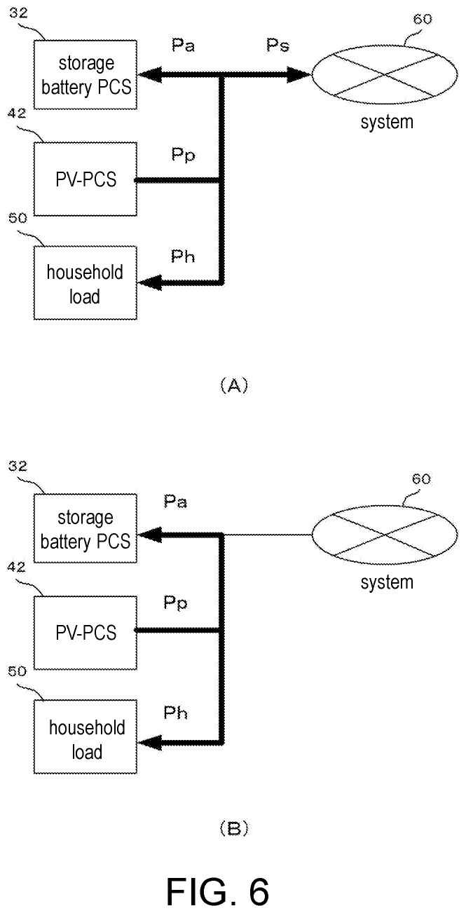

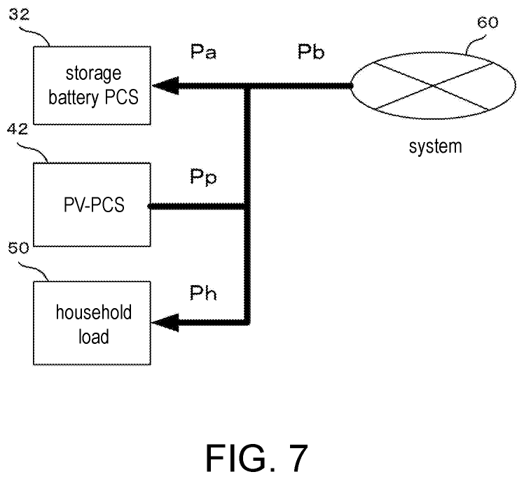

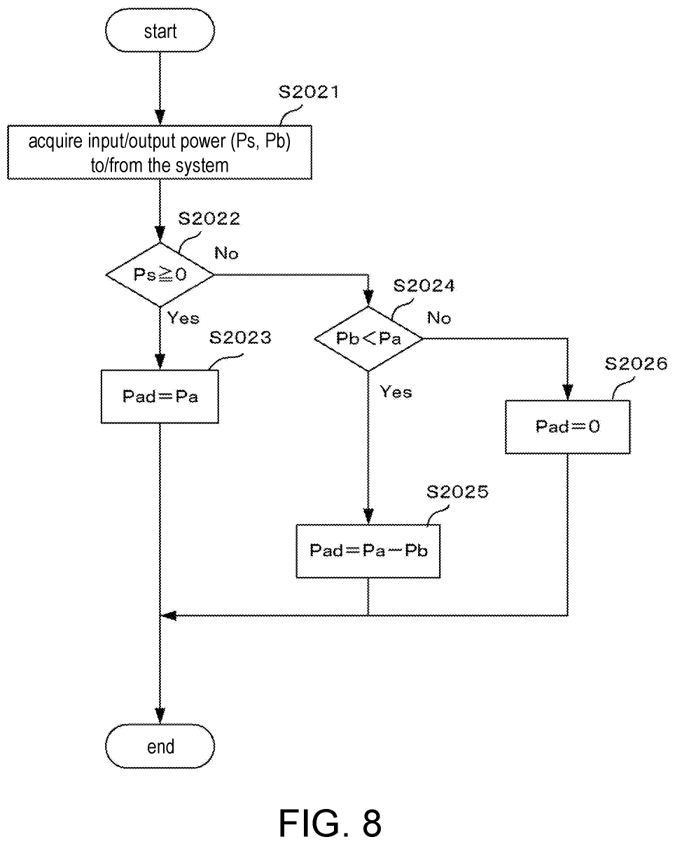

Here, a charged power (self-consumption) calculation subroutine is described.
FIG. 6A, FIG. 6B and FIG. 7 are diagrams illustrating a method of calculating the charged power (self-consumption). FIG. 8 is a flowchart illustrating the procedure of the charged power (self-consumption) calculation process in the control unit 22.
FIG. 6A and FIG. 6B are diagrams schematically showing input/output of power between the storage battery PCS 32, the PV-PCS 42, and the household load 50 shown in FIG. 1 and a commercial power system 60. FIG. 6A and FIG. 6B show a case where the storage battery 31 is charged and the power is sold to the system. Here, Pa is the charged power of the storage battery 31, Pp is the generated power of the PV 41, Ph is the power consumption of the household load, and Ps is the sold (reversely flowed) power to the system 60. Here, when the charged power (self-consumption) is presented as Pad, the charged power (self-consumption) Pad is a part of the charged power of the storage battery 31 which is carried by the generated power of the PV 41 except for the power input from the system 60.

In the state shown in FIG. 6A, in a system including the storage battery PCS 32, the PV-PCS 42, the household load 50, and the system 60, the power Ps is supplied to the system 60, but no power is supplied from the system 60, and thus all the charged power Pa of the storage battery 31 is carried by the generated power of the PV 41, and thus Pad=Pa is established.
In the state shown in FIG. 6B, Ps=0, but the same as in FIG. 6A, since no power is supplied from the system 60, all the charged power Pa of the storage battery 31 is also carried by the generated power of the PV 41 in this case, and thus Pad=Pa is established.

Similar to FIG. 6A and FIG. 6B, FIG. 7 is also a diagram schematically showing input/output of power between the storage battery PCS 32, the PV-PCS 42, the household load 50 shown in FIG. 1 and the commercial power system 60. FIG. 7 shows a case where the storage battery 31 is charged and power is purchased from the system. The reference signs are the same as in FIG. 6A and FIG. 6B, but here, Pb is the purchased power from the system 60. When the reference numeral is included as the input/output to/from the system 60, the purchased power is an input from the system 60, and thus Pb=−Ps.

In FIG. 7, in a case of the purchased power Pb<the charged power Pa, in the system including the storage battery PCS 32, the PV-PCS 42, the household load 50 and the system 60, the power is supplied from the PV 41 and the system 60, and thus, even if the storage battery 31 is charged, the part of the charged power Pa which is carried by the generated power of the PV 41 cannot be specified. Therefore, it is assumed that all of the purchased power Pb from the system 60 is used for charging the storage battery 31, the generated power of the PV 41 is partially consumed by the household load 50, and the rest is used for charging the storage battery 31, and it is estimated that the part of the charged power of the storage battery 31 excluding the purchased power is carried by the generated power of the PV 41. That is, Pad is calculated by Pad=Pa−Pb.
In FIG. 7, even in the case of the purchased power Pb≥the charged power Pa, in the system including the storage battery PCS 32, the PV-PCS 42, the household load 50 and the system 60, the power is supplied from the PV 41 and the system 60, and thus, even if the storage battery 31 is charged, the part of the charged power Pa which is carried by the generated power of the PV 41 cannot be specified. Therefore, it is assumed that all the generated power of the PV 41 is consumed by the household load 50, and only the purchased power is used for charging the storage battery 31. That is, Pad=0.

With reference to FIG. 8, the calculation process of the charged power (self-consumption) of the storage battery is described.
First, the management server 10 acquires the input/output power (Ps, Pb) to/from the system from the input/output power values to/from the system grasped in step S201 (step S2021). However, as described above, when the reference signs are included as the input/output to/from the system, Pb=−Ps. When the input/output current to/from the system and the system voltage are grasped as the input/output power index values, the input/output power to/from the system is calculated from these values, but when the power is acquired as the input/output power index values, the process in step S2021 may be omitted.

Next, the management server 10 determines whether the output power (Ps) to the system is 0 or more (step S2022).
When the output power (Ps) to the system is 0 or more (“Yes” in step S2022), the management server 10 calculates the charged power (self-consumption) (Pad) from Pad=Pa (step S2023) and ends the charged power (self-consumption) calculation process.

When it is determined that the output power (Ps) to the system is less than 0 (“No” in step S2022), the management server 10 compares the input power (Pb) from the system with the charged power (Pa) and determines whether Pb<Pa (step S2024).

When it is determined that Pb<Pa (“Yes” in step S2024), the management server 10 calculates the charged power (self-consumption) (Pad) by Pad=Pa−Pb (step S2025) and ends the charged power (self-consumption) calculation process.

When it is determined that Pb<Pa is not established (“No” in step S2024), the management server 10 calculates the charged power (self-consumption) (Pad) by Pad=0 (step S2026) and ends the charged power (self-consumption) calculation process.
In this way, when the management server 10 ends the charged power (self-consumption) calculation process in step S202, the management server 10 proceeds to step S203.

Next, the management server 10 reads a first count value and a second count value associated with the grasped apparatus ID (hereinafter referred to as the target apparatus ID) from the management DB 12 onto the memory (step S203). Moreover, initial values (values at the start of operation of the monitoring device 20) of the first count value and the second count value in the management DB 12 are both “0”.

Thereafter, the management server 10 determines whether the charged power (self-consumption) is equal to or less than a specified value (step S204). Here, the specified value is a value set in advance as a threshold value for determining that there is a possibility that a problem has occurred in the PV 41 inside the power generation system 40. The specified value may be a value stored in the management DB 12 for each power generation system 40 or a value set in the management server 10 and used in common for all the power generation systems 40. Here, the specified value corresponds to the predetermined amount.

When the charged power (self-consumption) is higher than the specified value (“No” in step S204), the management server 10 clears the first count value and the second count value associated with the target apparatus ID in the management DB 12 to “0” (step S221). In addition, the management server 10 diagnoses that there is no abnormality in “the power generation system 40 combined with the power storage system 30 having the target apparatus ID” (hereinafter referred to as the target power generation system 40) (step S222). Then, the management server 10 returns diagnosis result information in which the diagnosis result is set to the monitoring device 20 which is a transmission source of the charged power information received this time (step S210), and then ends the charged power information analysis process.

On the other hand, when the charged power (self-consumption) is less than or equal to the specified value (“Yes” in step S204), the management server 10 determines whether the charged power (self-consumption) is “0” (step S205). Then, when the charged power (self-consumption) is not “0” (“No” in step S205), the management server 10 adds “1” to the first count value (step S206). The process in step S206 is a process of adding “1” to each of the first count value on the memory and the first count value associated with the target apparatus ID in the management DB 12.

The management server 10 which has ended the process in step S206 determines whether the first count value is equal to or greater than a preset first threshold value (for example, “3”) (step S207). Then, when the first count value is less than the first threshold value (“No” in step S207), the management server 10 performs the same processes (the processes in steps S222 and S210) as in the case when the charged power (self-consumption) is more than the specified value, and then ends the charged power information analysis processing. Here, the first threshold value corresponds to a second predetermined number.

On the other hand, when the first count value is equal to or greater than the first threshold value (“Yes” in step S207), the management server 10 diagnoses that there is an abnormality in the PV 41 of the power generation system 40 (step S208). Next, the management server 10 stores the diagnosis result and the diagnosis date in the management DB 12 in association with the target apparatus ID (step S209). Moreover, when the management server 10 stores a diagnosis result indicating that there is an abnormality in the PV 41 or the PV-PCS 42 of the power generation system 40 in the management DB 12 in association with a certain apparatus ID, a message indicating that there is an abnormality in the PV 41 or the PV-PCS 42 of the power generation system 40 is displayed on the web page for confirming the action status of the power storage system 30 having the apparatus ID.

The management server 10 which has ended the process in step S209 returns diagnosis result information in which the diagnosis result is set to the monitoring device 20 which is the transmission source of the charged power information received this time (step S210), and then ends the charged power information analysis process.

In addition, when the charged power (self-consumption) is “0” (“Yes” in step S205), the management server 10 adds “1” to each of the first count value and the second count value (step S231). In the process in step S231, “1” is also added to each count value associated with the target apparatus ID in the management DB 12 as in the process in step S206.

The management server 10 which has ended the process in step S231 determines whether the second count value is equal to or greater than a preset second threshold value (for example, “3”) (step S232). Then, when the second count value is less than the second threshold value (“No” in step S232), the management server 10 performs the processes after step S207 which are already described. Here, the second threshold value corresponds to a first predetermined number.

In addition, when the second count value is equal to or greater than the second threshold value (“Yes” in step S232), the management server 10 diagnoses that there is an abnormality in the PV-PCS 42 of the power generation system 40 (step S233). Then, after performing the processes in steps S209 and S210, the management server 10 ends the charged power information analysis processing for the charged power information received this time.

Returning to FIG. 4, the description of the charged power information transmission process is continued.
As is clear from the contents of the above-described charged power information analysis process (FIG. 5), if the process in step S103 is performed, the diagnosis result information is transmitted from the management server 10. After receiving this diagnosis result information (step S104), the control unit 22 determines whether the received diagnosis result information is information indicating that there is an abnormality in the power generation system 40 (the PV 41 or the PV-PCS 42) (step S105).

Then, when the diagnosis result information is not the information indicating that there is an abnormality in the power generation system 40 (“No” in step S105), the control unit 22 ends the charged power information transmission process without performing any particular process. In addition, when the diagnosis result information is the information indicating that there is an abnormality in the power generation system 40 (“Yes” in step S105), the control unit 22 performs a notification process of displaying on the LCD 21 a message indicating that there is an abnormality in the PV 41 or the PV-PCS 42 according to the received diagnosis result information to notify the user, and ends the charged power information transmission process.

In this way, the presence or absence of abnormality of the power generation system 40 connected to the power receiving point the same as the power storage system 30 can be diagnosed without obtaining any information from the power generation system 40.

### Example 2

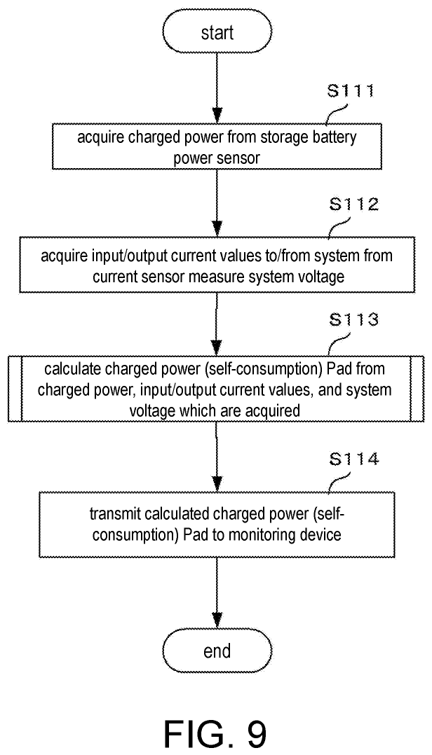

A monitoring system according to Example 2 of the disclosure is described below more specifically using the drawings.
Configurations and processes in common with Example 1 are denoted by the same reference signs, and detailed description thereof is omitted.
The schematic configuration and the usage form of the monitoring system according to the example, the schematic configuration of the controller 320 of the storage battery PCS 32, and the schematic configuration of the monitoring device 20 are the same as those of Example 1.
In Example 1, the monitoring device 20 acquires charged power from the storage battery power sensor 33, acquires input/output power values to/from the system from the storage battery PCS 32, and transmits information in which these data and the self-apparatus ID are set to the management server 10. Then, the charged power amount (self-consumption) is calculated by the management server 10. In contrast, in the example, in the storage battery PCS 32, the charged power amount (self-consumption) is calculated and transmitted to the management server 10 via the monitoring device 20, and a charged power analysis process is performed.

<Charged Power (Self-Consumption) Calculation Process, Charged Power Information Transmission Process and Charged Power Information Analysis Process>
FIG. 9 is a flowchart showing a procedure of the charged power (self-consumption) calculation process in the storage battery PCS 32 of the example.
First, the calculation/control portion 321 obtains charged power from the storage battery power sensor 33 (step S111).
Next, the calculation/control portion 321 acquires input/output current values to/from the system from the current sensor 35 and measures a system voltage (step S112).
Then, the calculation/control portion 321 calculates the charged power (self-consumption) from the charged power, the input/output current values, and the system voltage which are acquired (step S113). The content of the calculation process of the charged power (self-consumption) is the same as that in Example 1 shown in FIG. 8.
Next, the calculation/control portion 321 transmits the charged power (self-consumption) calculated in step S113 to the monitoring device 20 (step S114), and ends the process. Here, the function of calculating the charged power (self-consumption) in the calculation/control portion 321 of the storage battery PCS 32 corresponds to a calculation part.

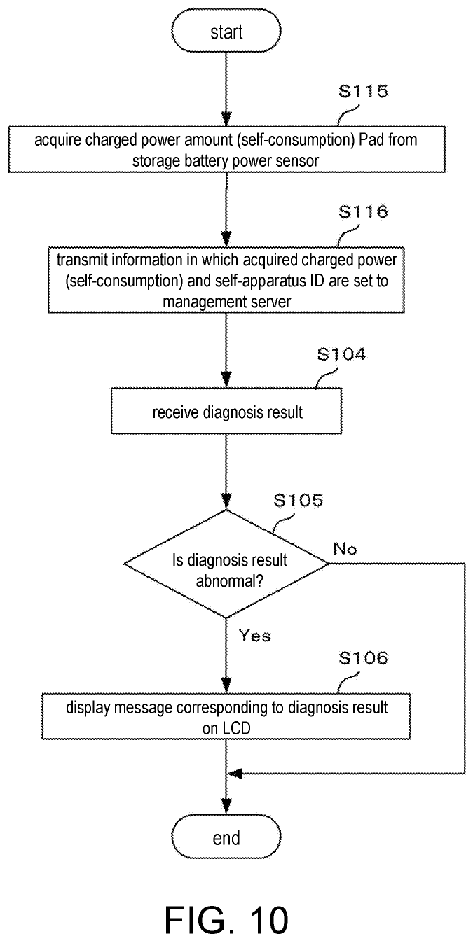

FIG. 10 is a flowchart showing a procedure of a charged power information transmission process in the monitoring device 20 of the example.
First, the control unit 22 of the monitoring device 20 acquires the charged power amount (self-consumption) from the storage battery PCS 32 (step S115).
Next, the control unit 22 transmits charged power information in a predetermined format in which the acquired charged power (self-consumption) and the self-apparatus ID are set to the management server 10 using the NIC 23 (step S116).
Subsequent processes after step S104 are the same as those in Example 1 shown in FIG. 4.

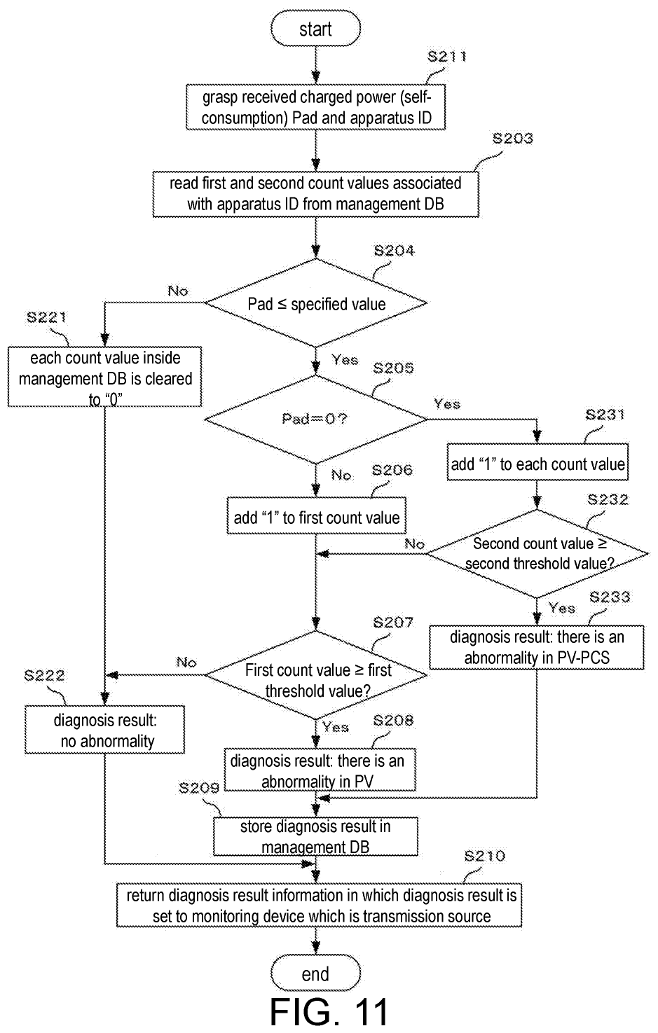

The management server 10 which has received the charged power information (self-consumption) starts a charged power information analysis process. FIG. 11 is a flowchart showing a procedure of the charged power information analysis process of the example.
First, the charged power (self-consumption) and the apparatus ID set in the received charged power information are grasped (step S211). Subsequent processes after step S203 are the same as those in Example 1 shown in FIG. 5.

In this way, the presence or absence of abnormality of the power generation system 40 connected to the power receiving point the same as the power storage system 30 can be diagnosed without obtaining any information from the power generation system 40.

### Example 3

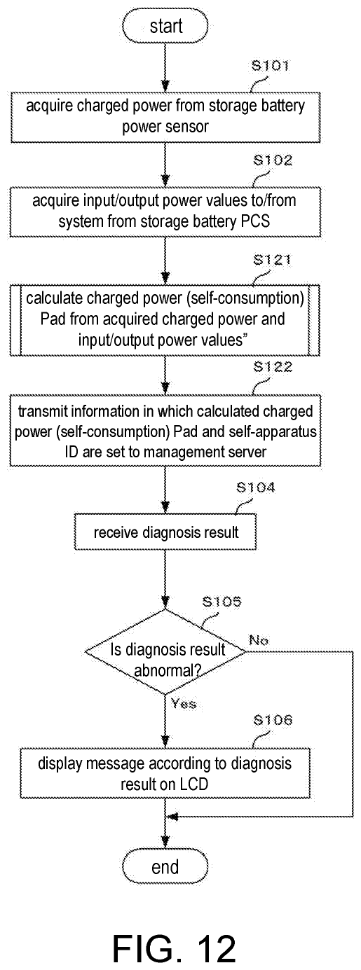

A monitoring system according to Example 3 of the disclosure is described below more specifically using the drawings.
Configurations and processes in common with Example 1 and 2 are denoted by the same reference signs, and detailed description thereof is omitted.
The schematic configuration and the usage form of the monitoring system according to the example, the schematic configuration of the controller 320 of the storage battery PCS 32, and the schematic configuration of the monitoring device 20 are the same as those of Example 1.
In Example 1, the monitoring device 20 acquires charged power from the storage battery power sensor 33, acquires input/output power values to/from the system from the storage battery PCS 32, and transmits information in which these data and the self-apparatus ID are set to the management server 10. Then, the charged power amount (self-consumption) is calculated by the management server 10. In contrast, in the example, the charged power amount (self-consumption) is calculated in the monitoring device 20 and transmitted to the management server 10, and the charged power analysis process is performed.

<Charged Power (Self-Consumption) Calculation/Transmission Process, Charged Power Information Transmission Process and Charged Power Information Analysis Process>
FIG. 12 is a flowchart showing a procedure of a charged power (self-consumption) calculation/transmission process in the monitoring device 20 of the example.
Step S101 and step S102 are the same as those in Example 1 shown in FIG. 4.
The control unit 22 calculates charged power (self-consumption) from the acquired charged power and input/output power values (step S121). The content of the calculation process of the charged power (self-consumption) is the same as that in Example 1 shown in FIG. 8.
Next, the control unit 22 transmits charged power information in a predetermined format in which the calculated charged power (self-consumption) and the self-apparatus ID are set to the management server 10 using the NIC 23 (step S122).
Processes after step S104 are the same as those in Example 1 shown in FIG. 4. Here, the function of calculating the charged power (self-consumption) in the control unit 22 corresponds to a calculation part.
The charged power analysis process in the management server 10 is the same as that in Example 2 shown in FIG. 11.

In this way, the presence or absence of abnormality of the power generation system 40 connected to the power receiving point the same as the power storage system 30 can be diagnosed without obtaining any information from the power generation system 40.

Moreover, in the following, in order to make it possible to compare the configuration requirements of the disclosure with the configuration of the examples, the configuration requirements of the disclosure are described with reference signs in the drawings.

### <Invention 1>

A monitoring system, including:
a calculation part (10, 22, 321) for calculating, based on first charged power index values indicating charged power of an power storage system (30) and input/output power index values indicating input/output power from a power receiving point (55) to which the power storage system (30) is connected to a system, second charged power index values indicating power charged by generated power of a power generation system connected to the power receiving point of the charged power of the power storage system; and
a diagnosis part (10) for diagnosing presence or absence of abnormality of the power generation system (40) based on the second charged power index values calculated by the calculation part.

What is claimed is:

1. A monitoring system, comprising:
a calculation part for calculating, based on first charged power index values indicating charged power of an power storage system and input/output power index values indicating input/output power from a power receiving point to which the power storage system is connected to a system, second charged power index values indicating power charged by generated power of a power generation system connected to the power receiving point of the charged power of the power storage system; and
a diagnosis part for diagnosing presence or absence of abnormality of the power generation system based on the second charged power index values calculated by the calculation part.

2. The monitoring system according to claim 1, wherein the diagnosis part diagnoses that there is an abnormality in the power generation system when a first predetermined number of the second charged power index values are all “0”.

3. The monitoring system according to claim 1, wherein the diagnosis part diagnoses that there is an abnormality in the power generation system when a second predetermined number of the second charged power index values are equal to or less than a predetermined amount.

4. The monitoring system according to claim 2, wherein the diagnosis part diagnoses that there is an abnormality in the power generation system when a second predetermined number of the second charged power index values are equal to or less than a predetermined amount.

5. The monitoring system according to claim 1, wherein the power generation system comprises a DC power generation device and a power conditioner which converts DC power from the DC power generation device to AC power; and
the diagnosis part diagnoses that there is an abnormality in the power conditioner of the power generation system when the first predetermined number of the second charged power index values are all “0”, and diagnoses that there is an abnormality in the DC power generation device of the power generation system when the second predetermined number of the second charged power index values are equal to or less than the predetermined amount.

6. The monitoring system according to claim 1, wherein when the diagnosis part diagnoses that there is an abnormality in the power generation system, a notification process for notifying a user of the power storage system of this diagnosis is performed.

7. The monitoring system according to claim 2, wherein when the diagnosis part diagnoses that there is an abnormality in the power generation system, a notification process for notifying a user of the power storage system of this diagnosis is performed.

8. The monitoring system according to claim 3, wherein when the diagnosis part diagnoses that there is an abnormality in the power generation system, a notification process for notifying a user of the power storage system of this diagnosis is performed.

9. The monitoring system according to claim 4, wherein when the diagnosis part diagnoses that there is an abnormality in the power generation system, a notification process for notifying a user of the power storage system of this diagnosis is performed.

10. The monitoring system according to claim 5, wherein when the diagnosis part diagnoses that there is an abnormality in the power generation system, a notification process for notifying a user of the power storage system of this diagnosis is performed.
